(19) United States
(12) Patent Application Publication
(10) Pub. No.: US 2026/0164617 A1
(43) Pub. Date: Jun. 11, 2026

(54) STABILITY CONTROL OPERATIONS IN COOLING SYSTEM WITH MULTIPLE LIQUID-TO-AIR HEAT REJECTION UNITS

(71) Applicant: Microsoft Technology Licensing, LLC, Redmond, WA (US)

(72) Inventors: Guixiang Ellen TAN, Portland, OR (US); Tzong Chian WU, New Taipei City (TW); Yimin ZHANG, Johns Creek, GA (US); Nisha Susan JOHN, Bothell, WA (US); Chin-Han CHAN, Taipei (TW); Tsunglin LIU, Taipei (TW); John Jason BRZOZOWSKI, Schwenksville, PA (US); Thiam Wah LOH, Singapore (SG); Xianfa ZHANG, Issaquah, WA (US); Naomi Yokogawa ROSELL, Issaquah, WA (US)

(21) Appl. No.: 19/061,065

(22) Filed: Feb. 24, 2025

Related U.S. Application Data
(60) Provisional application No. 63/730,226, filed on Dec. 10, 2024.

(51) Int. Cl. H05K 7/20

(52) U.S. Cl. CPC H05K 7/20836; H05K 7/20263; H05K 7/20781

(57) ABSTRACT

A cooling system includes multiple heat rejection units (HRUs) arranged in a parallel configuration to provide output flows that combine to form an input flow to an information technology (IT) rack. Each HRU concurrently executes flowrate equalization operations to equalize flowrate among the HRUs. The firmware sequence provides for operating an HRU in a flowrate control mode for a first predefined period of time with a flowrate setpoint set to a nominal HRU flowrate target. At the expiration of the first period of time, pressure is measured within the HRU and a pressure setpoint of the HRU is updated to store a measured pressure value. The HRU is then transitioned out of the flowrate control mode and into a pressure control mode that causes the HRU to regulate pump speed to ensure that a measured internal pressure matches the pressure setpoint.

### CROSS-REFERENCE TO RELATED APPLICATIONS

The present application claims priority to U.S. Provisional Patent Application Ser. No. 63/730,226, entitled “Stability Control Operations in Cooling System with multiple Liquid-To-Air Heat Rejection Units,” and filed on Dec. 10, 2024, which is hereby incorporated by reference for all that is discloses or teaches.

### BACKGROUND

Modern computing systems supporting artificial intelligence (AI) solutions typically process large quantities of transactions and therefore consume high levels of power and generate excessive heat. Traditional air-cooled server rack designs are incapable of meeting the increased cooling needs of these new AI and cloud platforms. Liquid cooling systems provide more cooling capability than air-cooled systems. However, data centers have been traditionally air-cooled, and few data centers are equipped with liquid cooling reservoirs. An alternative solution that is being adopted to meet these increased cooling demands involves utilizing liquid-to-air heat rejection units (HRUs) that do not require liquid cooling reservoirs. However, there are many challenges with liquid-to-air cooling technology, as this technology is not commonly used at large scale and has high power needs.

### SUMMARY

The described technology provides control operations for ensuring long-term stability of a cooling system that pumps liquid coolant through a computing system rack. The cooling system includes multiple heat rejection units (HRUs) that each include pumps and liquid-to-air heat exchangers. According to one implementation, the control operations include flowrate equalization operations that are performed by a control system within each multiple HRUs simultaneously or in a substantially concurrent manner. The flowrate equalization operations provide for fixing a flowrate setpoint within each of the HRUs to equal a flowrate target and driving the multiple HRUs in a flowrate control mode for a first period of time while coolant is pumped through the multiple HRUs and while the flowrate setpoints of the multiple HRUs are fixed to the flowrate target. Following expiration of the first predefined period of time, measurements are performed to measure pressure internal to each of the HRUs and a pressure differential setpoint of each of the HRUs is adjusted to the corresponding pressure that is measured within the HRU. Subsequent to adjusting the pressure differential setpoint of each of the HRUs, the flowrate control mode is disabled, and a pressure control mode is enabled within each of the HRUs.

The above presents a simplified summary of the innovation in order to provide a basic understanding of some implementations described herein. This summary is not an extensive overview of the claimed subject matter. It is intended to neither identify key or critical elements of the claimed subject matter nor delineate the scope of the subject innovation. Its sole purpose is to present some concepts of the claimed subject matter in a simplified form as a prelude to the more detailed description that is presented later.

Other implementations are also described and recited herein.

### BRIEF DESCRIPTIONS OF THE DRAWINGS

Examples are illustrated in referenced figures of the drawings. It is intended that the examples and figures disclosed herein are to be considered illustrative rather than restrictive.

FIG. 1 illustrates an implementation of a coolant system for a computing system rack.

FIG. 2 illustrates example flowrate equalization operations executable to implement aspects of the disclosed technology.

FIG. 3 illustrates example initialization operations for a heat rejection unit (HRU) in a cooling system employing aspects of the disclosed technology.

FIG. 4 illustrates an example computing device for use in implementing the described technology

### DETAILED DESCRIPTIONS

To provide increased cooling at data centers that support AI computing, cooling system engineers are exploring cooling architectures that utilize liquid-to air heat rejection units (HRUs). Designs that couple together multiple HRUs in a coolant loop are desirable due, in part, to the potential to provide increased HRU fault protection by allowing an IT rack and its respective computing hardware to remain online and fully operational when a single HRU fails and undergoes servicing. However, some HRUs lack the ability to communicate directly with one another, which presents challenges in configuring HRUs within a multi-HRU cooling system to respond to critical HRU failures in ways that do not upset long-term cooling system stability. The technology disclosed herein includes operational techniques that provide single-HRU fault protection while also ensuring long-term stability of a cooling system.

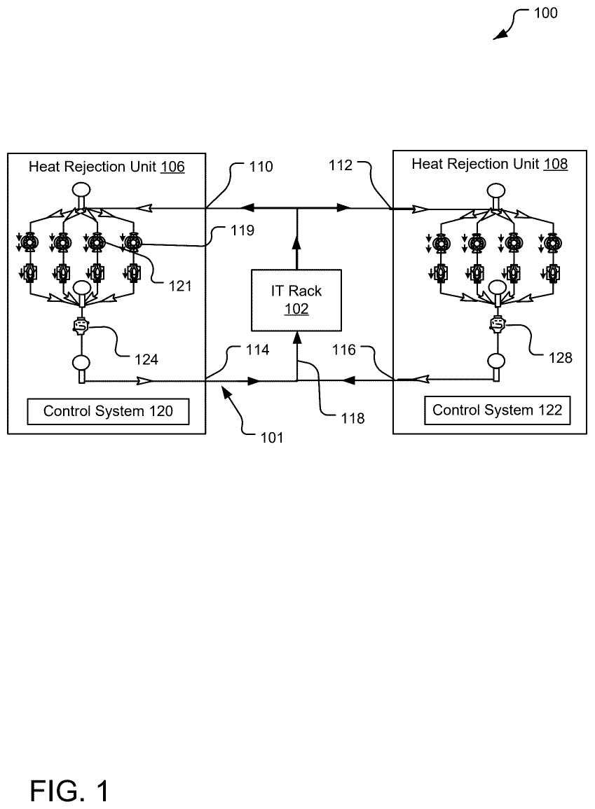

FIG. 1 illustrates an implementation of a cooling system that utilizes liquid-to-air heat rejection units (HRUs) to cool an information technology (IT) rack 102 (e.g., a computing rack storing supporting servers or other compute hardware). The cooling system 100 includes a first heat rejection unit (HRU) 106 and a second HRU 108 that pump a liquid coolant through a coolant loop 101. Hot coolant leaving the IT rack 102 is split into two component streams, each of which is received at an inlet 110 or 112 of a different one of the HRUs 106 and 108. The HRUs 106 and 108 function to pull heat away from the liquid coolant and redirect cooled coolant back to the IT rack 102. Post-cooling, the liquid coolant is output from the first HRU 106 at an outlet 114 and output from the second HRU 108 at an outlet 116. Coolant streams released from the outlets 114 and 116 are recombined to provide an input flow to the IT rack 102, referred to below as IT rack input flow 118.

The first HRU 106 and the second HRU 108 both include a plurality of pumps (e.g., pumps 119, 126) that pump liquid coolant into liquid-to-air heat exchangers (e.g., liquid-to-air heat exchangers 124, 128). The number of pumps may vary in different implementations and also across the HRUs of a single implementation; however, it is assumed that all of the HRUs in the cooling system 100 are capable of cooling a liquid coolant to a same temperature setpoint or same selectable temperature range. In FIG. 1, the first HRU 106 and the second HRU 108 are identical. In other implementations of the disclosed technology, the HRUs coupled to the IT rack 102 have different characteristics. In some implementations, more than two HRUs are coupled to a same IT rack 102. In other implementations, there may exist more than a single IT rack 102 in the cooling system 100. Features of an example HRU are described below with respect to the first HRU 106.

After the hot coolant is received at the inlet 110 of the first HRU 106, the coolant is split into a plurality of parallel channels, each of which includes a pump (e.g., the pumps 119, 121). In some implementations, the HRU 106 further includes a reservoir (not shown) that receives the coolant from the inlet 110 and that provides the coolant to the channels that include the pumps. Coolant outputs by the plurality of channels is then combined and pushed through a liquid-to-air heat exchanger 124. The hot liquid coolant from the IT rack 102 is cooled down as it passes through the liquid-to-air heat exchanger 124. In one implementation, the liquid-to-air heat exchanger 124 includes an intake with one or more fans that pull cold air in from the air conditioning system of the surrounding room. Within the liquid-to-air heat exchanger 124, heat from the liquid coolant is transferred to the air stream, and the air stream is provided back to an intake of the room's air conditioning system.

In FIG. 1, the first HRU 106 includes a control system 120, which is assumed to provide functionality identical to a control system 122 of the second HRU 108. This functionality includes autonomous and dynamic variation of HRU pump speed control to ensure that properties of the liquid coolant circuited through each HRU continuously matches a coolant flow characteristic (e.g., temperature, pressure, flowrate) that is dictated by a currently selected control mode of the HRU. In one implementation, the control system 120 controls the speeds of the pumps according to two alternate control modes, which include a flowrate control mode and a pressure control mode.

When the control system 120 is operated in the flowrate control mode, the control system 120 selectively varies pump speeds of the plurality of pumps in the first HRU 106 to fix a flowrate of the liquid coolant through the HRU according to a fixed flowrate setpoint such that the coolant leaving the outlet 114 has a constant flowrate, which is set by a programmable system parameter. Although not shown, the first HRU 106 includes at least one flowrate sensor that provides flow rate measurements as feedback that the control system 120, in turn, uses to selectively vary the pump speed when in the flow rate control mode.

Alternatively, when the control system 120 is operated in the pressure control mode, the control system 120 selectively varies the pump speeds of the plurality of pumps in the first HRU 106 to fix an internal pressure differential between inlet 110 (the hot port) and the outlet 114 (the cold port) that is calculated based on the pressure sensed within the coolant passing through first HRU 106 to a fixed pressure differential setpoint. Although not shown, the first HRU 106 includes at least two pressure sensors including a first sensor that is proximal to the inlet 110 and another sensor proximal to the outlet 114. Measurements collected by these pressure sensors are provided back to the control system 120 that, in turn, uses the pressure measurements to selectively vary the pump speed when in the pressure control mode.

During nominal operations of cooling system 100, the control system 120 is configured to selectively toggle the control mode of the first HRU 106 between the pressure control mode and the flowrate control mode in response to detection of a mode change trigger, which may vary in different implementations. Examples of mode change triggers include commands, such as externally initiated commands (e.g., transmitted by manual user input or computer applications) or internally initiated commands that are executed as part of programmed firmware sequence(s). For example, the control system 120 may execute a firmware sequence that automatically changes the control mode at preprogrammed time(s) or in response to sensing altered system state conditions such as valves opening or closing, couplings being detected by various sensors, and/or coolant properties such as pressure, flowrate or temperature satisfying predefined criteria. (e.g., pressure, flowrate, and/or temperature satisfying predefined criteria, valves opening or closing)

In addition to controlling the plurality of pumps internal to the first HRU 106 according to the currently-selected control mode and corresponding setpoint (e.g., a pressure differential setpoint or flowrate setpoint), the control system 120 controls the fans within the liquid-to-air heat exchangers (e.g., liquid-to-air heat exchanger 124) to ensure that coolant leaving the outlet 114 of the first HRU 106 is controlled to equal a fixed temperature setpoint. This temperature is a function of pump speed (of the plurality of pumps internal to the HRU 106), the fan speed for the plurality of fans within the liquid-to-air heat exchanger 124, the air temperature at an inlet to the liquid-to-air heat exchanger 124. Given a fixed temperature setpoint and current pump speeds, which are driven to control the liquid flow rate or pressure as described above, the control system 120 determines fan speeds that are adequate to ensure that the coolant leaving the outlet 114 has a temperature that equals the fixed temperature setpoint. For example, fan speeds may be retrieved via a lookup table based on temperature setpoint and current pump speed, or automatically adjusted through a proportional-integral-derivative (PID) control.

During nominal operating conditions, both the first HRU 106 and the second HRU are programmed to the same fixed temperature setpoint, which is selected to ensure that all coolant reaching the IT rack 102 is of a target temperature or target temperature range (e.g., a 1-2-degree temperature range). For various reasons, it is desirable to ensure that the coolant flow through the outlets 114 and 116 of the HRUs are of identical flow rates, meaning that the IT rack input flow 118 is comprised of a 50% contribution from the first HRU 106 and a 50% contribution from the second HRU 108. In a perfectly symmetrical system where the HRUs are identical to one another as well as equidistant to the IT rack 102 (with identical channel impedance values) and fully operational (with no defective pumps or fans), this can be achieved by operating both of the HRUs in the flowrate control mode with the flowrate setpoints set to 50% of a total IT Rack Flow Rate Target (e.g., the target flow rate through the IT rack 102). In this scenario, the pumps and fans of the first HRU 106 and the second HRU 108 operate at equal speeds, which ensures wear and tear that is even throughout the cooling system. Notably, if one of the HRUs is routinely operating its pumps at much higher speeds than the other, the lifetimes of the more heavily used pumps are shorted as compared to scenarios where all pumps in the coolant system are used evenly. Shorter component lifetimes lead to a higher maintenance burden and higher system operating costs as compared to scenarios where component lifetimes can be extended due to more evenly distributed system wear-and-tear. For this reason, it is desirable to operate the cooling system 100 in a way that ensures substantially even pump usage of all HRUs coupled to a same IT rack 102.

In addition to ensuring long-term even wear-and-tear, it is also desirable to operate the cooling system 100 in a manner that guarantees compliance with acoustic requirements that are commonly imposed on data centers and/or coolant system suppliers. When operated at high speeds, fans and pumps generate more noise. It is therefore a concern of coolant system suppliers to ensure that fans and pumps within each HRU are nominally operated within a target range of speeds that that exclude the highest speeds that the HRUs are capable of.

In systems that have a single HRU providing coolant to a single IT rack, the single HRU can typically experience a single-pump failure and still maintain its flow rate because the HRU's control system automatically tunes the pump speed of the remaining, functioning pumps to compensate for the single-pump failure. However, in such a system, the single HRU may not be able to sustain the target flow rate when a multi-pump failure is experienced. Consequently, an IT rack cooled by a single HRU may be at risk of overheating during a multi-pump failure scenario of the HRU. A common response to this type of multi-pump failure scenario is to power down the IT rack 102 (e.g., to safe components), and then take the single HRU offline for servicing or replacement.

To extend up-time of IT racks in the above-described types of critical HRU failure scenarios, it is desirable to modify the traditional, single-HRU configuration in a way that provides increased HRU fault protection. However, coupling multiple HRUs together in a same coolant loop does not, by itself, provide this desired redundancy in a straightforward manner. In many systems, HRUs lack the capability to communicate with one another. Therefore, if one HRU fails, the other HRUs do not receive notification of the failure or have reason to know they should change their flowrate set point(s) to a higher value to compensate for the reduced flow the failed HRU. Therefore, if all HRUs in a multi-HRU cooling system are operating in flowrate control mode, a multi-pump failure of one HRU can still lead to a scenario where the IT rack 102 experiences a drop in flowrate, placing the IT rack 102 at risk of damage. It is desirable to protect the IT rack 102 from damage in HRU failure scenarios, and also desirable to keep the IT rack 102 online while an HRU is being replaced.

An objective of the presently-disclosed technology is therefore to provide a multi-HRU cooling system that always guarantees fixed total flowrate through the IT rack 102, both during nominal operations and also at times when one of the HRUs 106 or 108 is taken offline for replacement or servicing. Achieving this first objective entail allowing the HRUs 106 and 108 to operate at different flowrates for at least short periods of time such that one may compensate for the failures of the other. However, a secondary objective of the presently-disclosed technology is to ensure substantially equal wear-and-tear of the HRUs 106 and 108 during long-term nominal steady state operations when no HRU has failed. Achieving this second objective entails operating the HRUs 106 and 108 at identical flowrates during those nominal operations when no pumps are malfunctioning.

One seeming solution that could ensure the total flowrate delivered to the IT rack 102 remains constant in a single-HRU failure scenario is to drive the HRUs 106 and 108 in the pressure control mode with respective pressure differential setpoints set to equal the same (identical) pressure target. This could, theoretically, allow one HRU to automatically speed up its pumps when another HRU fails to deliver the same total amount of flowrate to the IT rack (due to a drop in pressure that is caused by the failure and sensed by the HRUs). Notably, this would result in a temporary imbalance between the respective contributions of the HRUs to the IT rack input flow 118, while keeping total flowrate through the IT rack 102 the same. Permitting this type of temporary flowrate imbalance desirably protects the IT rack 102 during the time that it takes to respond to a multi-pump failure while also remaining the IT rack 102 to remain powered on while the failed HRU is being replaced.

Unfortunately, trials have shown that it is not viable to continuously drive the HRUs 106 and 108 in the pressure control mode with equal pressure differential setpoints for multiple reasons. A first factor complicating operation of the HRUs 106 and 108 in the pressure control mode is that this mode tends to make the cooling system 100 highly vulnerable to small instabilities that, in turn, disrupt the balance of flowrates from the different HRUs over long periods of time. A second factor complicating operation of the HRUs 106 and 108 in the pressure control mode is the difference in natural impedance that exists along paths between the IT rack 102 and the different system HRUs. These impedance path differences make it impossible, in most cases, to preserve equal flow contributions (e.g., a 50/50 split) to the IT rack input flow 118 when all of the HRUs are fixed to the same pressure differential setpoint and operated in the pressure control mode. For example, if one HRU is closer to the IT rack 102 than another HRU coupled to the same coolant loop, the output stream of the closer HRU has lower net impedance, leading to a higher flowrate when the pressure differential setpoint is set to the same pressure target as the HRU with <2% of higher impedance. Therefore, instead of a 50/50 contribution to the IT rack input flow 118 by the first HRU 106 and the second HRU 108, there may be a split, such as 40/60, due to this unequal impedance. For the above-described reasons, it is typically not realistic to realize equal flowrate contribution to the IT rack 102 when the HRUs are operated in the pressure control mode with the pressure differential setpoints set to equal the same target.

The herein-disclosed HRU control operations include operational techniques that satisfy the seemingly competing objectives of (1) ensuring online HRU(s) can automatically increase pump speed and vary their own respective flow rates to compensate for multi-pump failure of another HRU in a multi-HRU cooling system (e.g., such that the IT rack input flow 118 is maintained at the target flow rate throughout a single-HRU failure scenario) while also (2) ensuring that all HRUs in the multi-HRU cooling system provide equal flow contribution to the IT rack 102 during times of ongoing nominal operation, even in implementations where the HRUs are of unequal distance to the IT rack 102 with unequal net impedances in respective coolant channels. Satisfying the first objective ensures the IT rack 102 safely can remain online while a single one of the HRUs is malfunctioning or taken offline for replacement. Satisfying the second objective ensures compliance with acoustic requirements and also ensures substantially equal wear-and-tear on pumps and fans throughout all nominal operations of the cooling system 100, which extends component lifetimes and reduces maintenance costs.

The above objectives are satisfied, at least in part, by executing a sequence of operations-referred to herein as “flowrate equalization operations”-when the HRUs in the same coolant loop are first turned on in a new system or when the cooling system 100 is turned on after being disabled for a period of time. In one implementation, the flowrate equalization operations are performed by the control system of each individual HRU in the cooling system 100. Although the HRUs 102 and 104 in the cooling system 100 may lack the ability to communicate with one another directly, their respective control systems (e.g., control system 120 and control system 122) include communication systems that receive signals from and transmit signals to an external processing system, such as a rack controller. The control systems 120 and 122 may include on-board memory storing firmware sequences that executed in response to externally-originating command(s) or detected events.

In one implementation, the flowrate equalization operations are stored as a firmware sequence that is executed by an HRU control system (e.g., the control system 120 or 122) in response to receiving an external command or detecting a predefined trigger event. In another implementation, the flowrate equalization operations are driven by a sequence of externally-originating commands. For example, an external operator or application transmits a command or command sequence that is received at the first HRU 106 and the second HRU 108 at approximately the same point in time (e.g., +/−a few seconds). In still another implementation, the flowrate equalization operations are executed as a calibration performed with sampling units before the cooling system is brought online. Following the calibration, pressure differential setpoints measured during the calibration (as described below) are applied to the production HRUs for pressure control directly in the data center.

In still another implementation, the control system 120 executes the flowrate equalization operations autonomously in response to sensing a predefined state condition or combination of state conditions, such as in response to detecting a new coupling to an unpressurized coolant channel of the coolant system 100. For example, the control system 120 may detect a coupling between the HRU 106 and the coolant loop 101 and transmit a signal that instructs other HRUs of the cooling system 100 to initiate the flowrate equalization operations. Notably, this latter implementation depends upon intercommunication capability between the different HRUs of the cooling system 100 and not all implementations support inter-HRU communications.

### Flowrate Control Operations

In the cooling system 100, control system 120 of the first HRU 106 initiates the flowrate equalization operations at approximately the same point in time (e.g., +/−a few seconds) as the control system 122 of the second HRU 108. These operations are described below with respect to the HRU 106, but it is understood that the cooling systems of both HRUs execute the described operations in unison.

When flowrate equalization operations commence within the HRU 106, the control system 120 first configures the first HRU 106 to operate in the flowrate control mode with the flowrate setpoint fixed to a nominal HRU flowrate target. The nominal HRU flowrate target is, in one implementation, a preselected, programmed value that is identical for all HRUs coupled to a same coolant loop and that represents an equal “split” of the IT Rack Target Flowrate (e.g., total flow through the IT rack 102) between the HRUs. The nominal HRU flowrate target is also a flowrate that is attainable by each of the system HRUs individually without driving HRU fans high enough to exceed the acoustic limit.

Once the first HRU 106 is placed in the flowrate control mode with the flowrate setpoint set to equal the nominal HRU flowrate target, the control system 120 operates the HRU 106 nominally while coolant is flowing through a coolant loop 101 of the cooling system 100 for a first predefined period of time. During this period of time, pressure increases throughout the coolant loop 101 and the flowrates of all system HRUs gradually rise to and stabilize at the fixed flowrate target.

By the expiration of the first predefined period of time, the flowrate of the first HRU 106 has stabilized to equalize the nominal HRY flowrate target. At this point in time, the control system 120 communicates with pressure sensors (not shown) within the HRU 106 to measure a pressure internal to the HRU 106—e.g., a pressure differential between or singular pressure between the inlet 110 and the outlet 114. The pressure internal to the HRU 106 is given by its flowrate multiplied by its net impedance. Therefore, it is possible that due to impedance differences, the pressure measured internal to the first HRU 106 may be different from the pressure measured internal the second HRU 108 when the flowrates of the two HRUs are equal.

After measuring the pressure internal to the first HRU 106, the control system 120 sets the pressure differential setpoint target of the first HRU 106 to equal the measured pressure value and then toggles the first HRU 106 into the pressure control mode by disabling the flowrate control mode and enabling the pressure control mode.

The same operations described above with respect to HRU 106 are also performed within the HRU 108 and in a substantially concurrent manner such that each “step” in the flowrate equalization operations is performed on the second HRU 108 within a few seconds (e.g., less than 1 second) of the same step being performed on the HRU 106. Like the first HRU 106, the second HRU 108 is operated in the flowrate control mode with the flowrate setpoint fixed to a nominal HRU flowrate setpoint for the first predefined period of time. Then, upon expiration of the first predefined period of time, a pressure or pressure differential is measured internal to the second HRU 108 and the pressure setpoint is adjusted to match the measured pressure value or differential. The second HRU 108 is transitioned into the pressure control mode following the adjustment of the pressure setpoint.

At the time of the above-described control mode change, the first HRU 106 and the second HRU 108 may have different internal pressures (each now self-regulating in the pressure control mode to maintain that pressure); however, the first HRU 106 and the second HRU 108 have equal flowrates because the pressure measurements were taken at a point in time when the flowrates were equal to one another.

While the HRUs operates in the pressure control mode, the respective control systems 120, 122 self-regulate to maintain their corresponding pressure differential setpoints, which allows for dynamic variation in the flowrate through the HRU 106 or 108 if any failure happens such that the total flowrate going to the IT rack 102 may remain unchanged and match the IT Rack Flowrate Target at all times. Interestingly, if the first HRU 106 experiences a minor failure, such as a single-pump failure, the first HRU 106 may be able to fully compensate for the failed pump and continue supply the same flowrate as before, provided that the first HRU 106 has sufficient multi-pump redundancy. However, if the first HRU 106 experiences a more critical failure scenario (e.g., a multi-pump failure) and is unable to match the flow rate of the second HRU 108, a pressure change may result within the coolant loop 101. This pressure change is sensed by both the first HRU 106 and the second HRU 108, causing both of the HRUs to increase their respective pump speeds. In this case, the second HRU 108 (which is not experiencing pump failure) may provide a much higher flowrate than the first HRU 106—e.g., a flow rate that is sufficient to ensure the IT rack 102 receives the full IT Rack Flowrate Target during the time that the first HRU 106 is malfunctioning and offline for replacement.

Notably, further challenges can arise following HRU replacement if operation continues in the pressure control mode. For example, when a new HRU replaces the failed HRU 106 and is first turned on, the new HRU may fail to engage because the second HRU 108 is already providing the full IT Rack Flowrate Target to the IT rack 102 and is configured to alter its flow exclusively when its internal pressure deviates from the target pressure differential setpoint. In this scenario, the new HRU may be turned on (replacing HRU 106) while the internal pressure of the second HRU 108 matches the pressure setpoint of the second HRU 108. The new HRU may, for instance, lack logic that facilitates any type of calibration or equalization of the load when initially brought online. This is not ideal, since this scenario may result in ongoing unequal load distribution.

According to one implementation, the foregoing challenges are addressed by controlling the HRUs of the cooling system 100 to perform a sequence of “new HRU initialization operations” following replacement of an HRU. Assume that during nominal operations, the first HRU 106 fails and is taken offline and subsequently replaced with a new HRU unit, referred to in the following description as “the new HRU.” The new HRU is coupled to the coolant loop (which includes the second HRU 108 and the IT rack 102) in a manner identical to the configuration of the first HRU 106. Following this HRU replacement, one or more commands are transmitted to the control system of the new HRU, and this triggers execution of the “new HRU initialization operations,” described below.

### New HRU Initialization Operations

When the new HRU is first turned on, both the new HRU and the second HRU 108 may be initially operating in the pressure control mode, as this mode is the “steady state” operational mode that ensues following the above-described flowrate equalization operations. However, upon commencement of the new HRU initialization operations, the control system of the new HRU adjusts the flowrate setpoint of the new HRU to equal a nominal HRU flowrate target. The predefined flowrate target is a preprogrammed value that is, in one implementation, determined by dividing the IT Rack Flowrate Target by the number of HRUs feeding the input stream that is passed into the IT rack 102. For example, in the illustrated architecture with two HRUs, the nominal HRU flowrate target may be 50% of the IT Rack Flowrate Target.

With the flowrate setpoint of the new HRU now fixed to the nominal HRU flowrate target, the new HRU is switched, by its respective control system, from the pressure control mode to the flowrate control mode. This switch to the flowrate control mode causes the new HRU to engage and begins circulating coolant, which increases pressure within the coolant loop. While this is occurring, the second HRU 108 is still operating in the pressure control mode. Therefore, the increase in pressure of the coolant loop causes the second HRU 108 to slow its pumps down to drive its internal pressure back to the target pressure setpoint. Eventually, the flowrate trough the first HRU 106 ramps to the nominal HRU flowrate target and the internal pressure of the second HRU 108 again stabilizes to the target pressure setpoint.

When operating in this configuration (e.g., with the new HRU in the flowrate control mode and the second HRU 108 in the pressure control mode), the flowrates of the second HRU 108 stabilizes to also approximately equal the nominal HRU flowrate target duc. This is because the pressure setpoint of the second HRU 108 was initially set (e.g., during the flowrate equalization operations) to ensure a match to a flowrate of the first HRU 106 whenever the first HRU 106 is operating at the predefined target flowrate. Upon the expiration of a second predetermined period of time following the placement of the new HRU in the flowrate control mode, the flowrates through the two HRUs have stabilized to approximately equal one another. The internal pressure differential is then measured within the new HRU and the pressure differential setpoint of the new HRU is updated to equal this measured pressure differential. Following this pressure differential setpoint update, the new HRU is transitioned back into the pressure control mode. At this point, both HRUs are running in normal operating condition (e.g., self-regulating pump speed in the pressure control mode) to cool the IT rack 102.

In the HRU initialization operations described above, it is possible that initial engagement of the new HRU could, in some scenarios, lead to an undesirable spike in flowrate through the IT rack 102 that exceeds the target flow rate that the IT rack 102 is expecting (the “IT rack target flow rate”). If the second HRU 108 is independently providing a flow rate to the IT rack 102 that is equal to the IT rack target flow rate at the time that the HRU initially engages, the addition of the flow contribution from the new HRU may temporarily increase the total flow through the IT rack 102 during the brief period of time that it takes the second HRU 108 to react by slowing its pumps. In this scenario, the momentary total flowrate could become so high as to risk potentially bursting a pipe or overshooting the target temperature of coolant delivered to the IT rack 102. To solve this issue, the following multi-stage procedure can be employed to slowly engage the new HRU 106.

First, when the new HRU is initially turned on in the flowrate control mode, the flowrate setpoint of the new HRU may be reduced relative to the nominal HRU target flowrate. For example, the flowrate setpoint of the HRU may be set to deliver approximately 50% of its target flowrate for a period of time. Once the second HRU 108 has reduced its pump speed and stabilized its internal pressure, the new HRU is contributing ¼ of the total flowrate to the IT rack 102 and the second HRU 108 is contributing ¾ of the total flowrate to the IT rack 102.

Then, following the above, the flowrate setpoint of the new HRU is increased to its true target (e.g., ½ of the IT Rack Target Flow Rate) and allowed to continue operating in the flowrate control mode for a second predefined period of time. This increase in flowrate from the new HRU again increases pressure in the coolant loop, causing the second HRU 108 to react by slowing its pumps, which causes the flowrates of the first HRU 106 and the second HRU 108 to stabilize to equal one another. After that, new HRU is transitioned into the pressure control mode with the measure pressure differential as the new setpoint. At the time that the new HRU is transitioned into the pressure control mode, both HRUs are operating with equal flowrates that match the nominal flowrate target, the new pump is engaged, and there is again a 50/50 contribution to the IT rack input flow 118 by the two HRUs.

The purpose of gradually ramping up the flow rate of the new HRU per-this multi-stage process is to reduce the total variation in flowrate through the IT rack 102, as abrupt shifts in this flowrate can lead to temporary (but sudden) temperature differences that impact performance of the IT rack 102. If, for example, there is a dramatic and sudden increase in coolant flowrate, this might cause a temporary increase in coolant temperature in the new HRU, and it may take a few moments for the HRUs to increase their fan speeds and thereby stabilize the coolant temperature back to the target temperature setpoint. When an HRU is out-of-service and replaced with a new unit, and the HRUs are operating in the pressure control mode, there is typically a lesser shift in the coolant flow rate through the IT rack when the transition between the pressure control mode in HRU 108 and the flowrate control mode for HRU 106 is to a reduced flowrate target (e.g., approx. 50% the flowrate target) as compared to a transition directly to the full flowrate target.

If the total flowrate is still too high temporarily during the above-described multi-stage process, more steps can be added with smaller flowrate increases to achieve a more smooth but longer initialization operation.

To ready the system for possible subsequent pump failure, the “new HRU initialization operations” may be followed by the above-described “flowrate equalization operations.” This entails measuring the respective internal pressures of HRUs at a time when the flowrates are equal to one another and the nominal HRU flowrate target (e.g., immediately upon termination of the new HRU initialization operations), fixing the pressure control mode setpoint of each HRU to the respective measured pressure value, and transitioning the HRU control mode from the flowrate control mode to the pressure control mode.

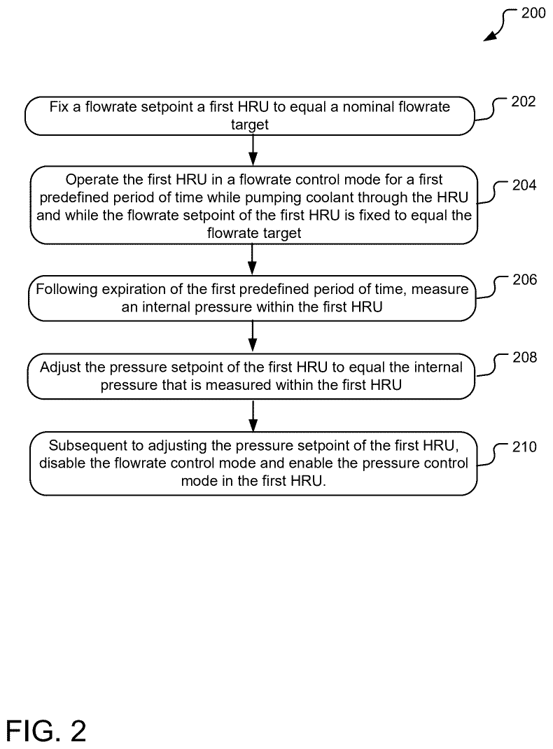

FIG. 2 illustrates example flowrate equalization operations 200 executable to implement aspects of the disclosed technology. In one implementation, the flowrate equalization operations are performed simultaneously or substantially concurrently (e.g., with less than a few second lag time) by a control system within each one of multiple HRUs coupled to a same coolant loop. In one implementation, the coolant loop flows a liquid coolant and each of the HRUs includes a plurality of internal channels, each including a pump that draws current through a corresponding liquid-to-air heat rejection unit. Flows output by the different HRUs are combined to provide an input flow to an IT rack.

In one implementation, the flowrate equalization operations 200 are commenced when an external device, such as a rack controller, transmits a flowrate equalization command to each of the HRUs coupled to the coolant loop. For example, the flowrate equalization operations 200 may be executed when the cooling system is initially brought online or when the cooling system is being returned to a nominal operative state following replacement of one or more HRU component(s), such as pumps or fans.

During a flowrate setpoint operation 202, a flowrate setpoint of a first HRU is fixed to a nominal HRU target flowrate, which is a predefined value that is equal for all the HRUs operating in parallel within the same cooling system. If, for example, the first HRU is arranged in parallel with one other HRU (as in the configuration of FIG. 1), the nominal target flowrate may be set such that each one of the two HRUs independently provides 50% of the IT Rack Flowrate Target. The nominal HRU target flowrate is a flow rate can be reached by the first HRU without driving system fans or pumps high enough to exceed a maximum volume level that is defined within acoustic requirements set by a governing party within an applicable jurisdiction.

Since the flow rate equalization operations 200 are performed concurrently on all HRUs of the multi-HRU system, other HRU(s) in the cooling system perform the flowrate setpoint operation 202 at a time substantially concurrent to (e.g., within a few seconds of) the flowrate setpoint operations 202 within the first HRU.

In one implementation, each HRU of the cooling system includes a control system that selectively regulates flow through the HRU according to either a flowrate control mode or a pressure control mode. When the control system operates in the flowrate control mode, the control system selectively varies pump speeds of pumps within the corresponding HRU to fix a flow rate of the coolant through the HRU to a fixed flowrate setpoint. Alternatively, when the control system operates in the pressure control mode, the control system selectively varies the pump speeds of the pumps within the HRU to fix a measured pressure within the HRU to a fixed pressure differential setpoint.

Following the flowrate setpoint operation 202 performed by the first HRU, a driving operation 204 drives the first HRU in the flowrate control mode for a first predefined period of time while coolant is being pump through the first HRU and while the flowrate setpoint of the first HRU is set to equal the first HRU target flow rate. Since the flow rate equalization operations 200 are performed concurrently on all HRUs of the multi-HRU system, other HRU(s) in the cooling system are likewise driven in the flowrate control mode, during the same time interval as the first HRU and for the predefined period of time. During this time period, flowrates within the different HRUs stabilize to equal the nominal target flowrate.

A pressure measurement operation 206 measures an internal pressure (or pressure differential) within the first HRU following expiration of the first predefined period of time, and a pressure adjustment operation 208 adjusts a pressure setpoint of the first HRU to equal the pressure that is measured within the first HRU during the pressure measurement operation 206. This operation is likewise performed independently by all HRUs within the cooling system such that each HRU is then configured with a pressure setpoint equal to its internal pressure that is measured upon the expiration of the first predefined period of time. At this point in time, the different HRUs may have different pressure differential setpoints corresponding to the internal pressures respectively measured at the point in time when HRUs are operating with equal flowrates (e.g., the nominal target flowrate).

Subsequent to the pressure adjustment operation 208, a mode switch operation 210 disables the flowrate control mode and enables the pressure control mode in the first HRU. This mode switch is performed in a substantially concurrent manner (e.g., concurrent to within a few seconds) in each other HRU in the system. At this point in time, the HRUs operate indefinitely in the pressure control mode with internal pressures maintained at the respective pressure differential setpoints set as described above (e.g., by measuring internal HRU pressure when the HRUs are operating with flowrates that equal the nominal target flow rate and one another).

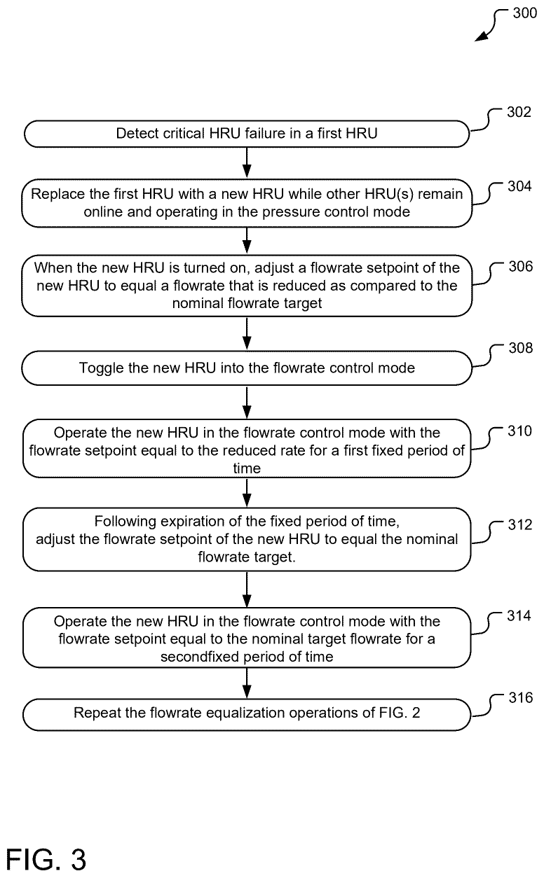

FIG. 3 illustrates example new HRU initialization operations 300 that may commence upon failure of an individual HRU in a cooling system with multiple HRUs configured in parallel. A detection operation 302 detects a critical HRU failure in a first HRU. The critical HRU failure may, for example, be a multi-pump failure or other component failure that results in a scenario where the first HRU is unable to maintain coolant flow at a nominal flowrate target (e.g., as defined in FIG. 1) or unable to maintain an internal pressure drop that matches a target pressure differential setpoint.

In one implementation, the multiple HRUs are operating in a pressure control mode with setpoints configured by performing the flowrate equalization operations 200 of FIG. 2. When operating in this mode, the critical failure of the first HRU may cause a pressure drop that causes other HRU(s) within the cooling system to increase their own pump speeds in effort to maintain internal pressure at their respective pressure setpoints. Through this action, the other fully operational HRU(s) fully compensate for the critical HRU failure of the first HRU, which ensures that is no reduction in the flowrate of coolant that is delivered to the IT rack (e.g., the IT Rack Flowrate Target is maintained).

In response to the detection operation 302, a servicing operation 304 replaces the first HRU with a new HRU. Throughout the servicing and replacement, other HRUs within the coolant loop may remain online and continue cooling an IT rack by delivering coolant to the IT rack that is of a target temperature and flowrate equal to the IT Rac Flowrate Target.

Once the new HRU is turned on at the conclusion of the servicing operation 304, a flowrate adjustment operation 306 adjusts a flowrate setpoint of the new HRU to equal a flowrate that is reduced (a “reduced flowrate”) as compared to a nominal HRU flowrate target that is programmed for all HRUs within the cooling system. The nominal HRU flowrate target is, for example, set as described with respect to FIG. 2 (e.g., such that each HRU provides an equal fraction of the IT Rack Flowrate Target). The reduced flowrate is, for example, set to equal ¼, ½, or some other fractional portion of the nominal flowrate target.

An operational mode toggle operation 308 toggles the new HRU into the flowrate control mode with the flowrate setpoint equal to the reduced flowrate. A driving operation 310 drives the new HRU in the flow rate control mode for a first predefined period of time (which may be different from the first predefined period of time described with respect to the flowrate equalization operations 200). During the first predefined time period that the new HRU is operated in the flowrate control mode, the other HRUs in the cooling system are operated in the pressure control mode. Therefore, the flowrate ramp-up of the new HRU causes a pressure decrease that is detected by the other HRU(s). In response, the other HRU(s) slow pumps, allowing their internal pressures to again re-stabilize to the pressure setpoint values. The first predefined period is preselected to be long enough to ensure that the pressure has time to stabilize throughout the system following the flowrate ramp-up of the new HRU to the reduced flow rate target.

Upon expiration of the first predefined period of time, a second adjustment operation 312 adjusts the flowrate setpoint of the new HRU to equal the nominal flowrate target and a driving operation 314 drives the new HRU in the flowrate control mode at the nominal HRU flowrate target for a second predefined period of time. As the flowrate ramps up within the new HRU between the reduced flowrate target and the nominal flowrate target, the other HRU(s) detect another pressure increase and respond by slowing their pumps until their internal pressures again stabilize at the respective target pressure setpoints. The second predefined period of time is preselected to be long enough to ensure that the pressure has time to stabilize throughout the system following the flowrate ramp-up of the new HRU to the nominal flowrate target.

Upon expiration of the second predefined period of time, the new HRU is operating in the flowrate control mode at the nominal HRU flowrate target and the other HRU(s) are operating in the pressure control mode with pressure setpoints set as described with respect to the flowrate equalization operations of FIG. 2. The operations 300 have succeeded in allowing the new HRU to fully engage and ramp up to the nominal flowrate target in a controlled manner that prevents even momentary overshoot of the flowrate delivered to the IT rack (e.g., ensuring the actual flow delivered to the IT rack matches the IT Rack Target Flow Rate and does not exceed the IT Rack Target Flow Rate when the new HRU is first engaged).

Following the driving operation 314, nominal operations of the system are restored by a flowrate equalization operation 316 that commences the flowrate equalization operations 200 of FIG. 2 in all HRUs of the cooling system. These operations generally provide for driving all HRUs at the nominal target setpoint, measuring a current pressure within each of the HRUs after a predefined period of time, adjusting the pressure setpoint of the HRUs to equal their respective newly-measured pressure values, and toggling the HRUs back into the pressure control mode.

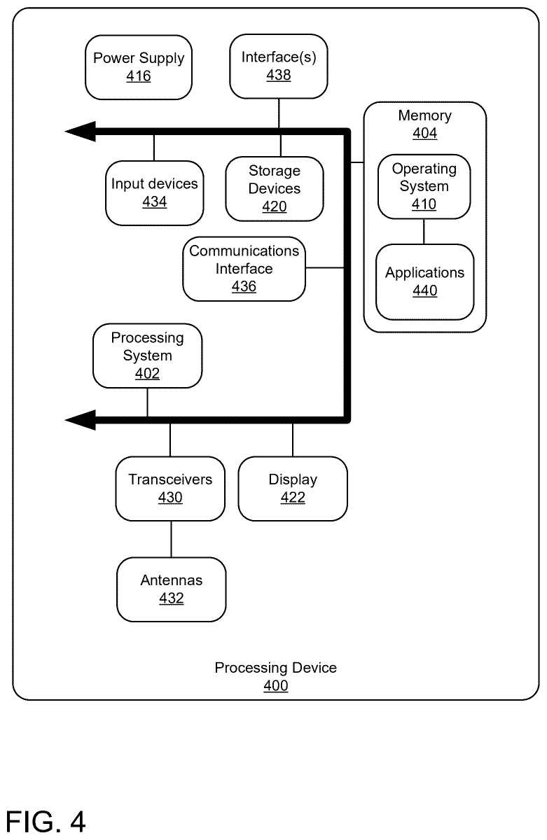

FIG. 4 illustrates an example computing device 400 for use in implementing the described technology. The computing device 400 may be a heat rejection unit (e.g., HRU 106 in FIG. 1) or a client computing device that transmits commands or command sequences to an HRU. For example, the client computing device may be a laptop computer, a desktop computer, a tablet computer, a server/cloud computing device, an Internet-of-Things (IoT), any other type of computing device, or a combination of these options. The computing device 400 includes one or more hardware processor(s) 402 and a memory 404. The memory f04 generally includes both volatile memory (e.g., RAM) and nonvolatile memory (e.g., flash memory), although one or the other type of memory may be omitted. An operating system 410 resides in the memory 404 and is executed by the processor(s) 402. In some implementations, the computing device 400 includes and/or is communicatively coupled to storage 420.

In the example computing device 400, one or more software modules, segments, and/or processors, such as applications 450 (e.g., applications for executing the herein-described flowrate equalization operations or the HRU replacement initialization operations) are loaded into the operating system 410 on the memory 404 and/or the storage 420 and executed by the processor(s) 402. The storage 420 may store commands or firmware sequences executable to perform the herein-described flowrate equalization operations or the HRU replacement initialization operations.

The computing device 400 may include one or more communication transceivers 430, which may be connected to one or more antenna(s) 432 to provide network connectivity (e.g., mobile phone network, Wi-Fi®, Bluetooth®) to one or more other servers, client devices, IoT devices, and other computing and communications devices. The computing device 400 may further include a communications interface 436 (such as a network adapter or an I/O port, which are types of communication devices) that is used to establish connections over a wide-area network (WAN) or local-area network (LAN). It should be appreciated that the network connections shown are exemplary and that other communications devices and means for establishing a communications link between the computing device 400 and other devices may be used.

The computing device 400 may include one or more input devices 434 such that a user may enter commands and information (e.g., a keyboard, trackpad, or mouse). These and other input devices may be coupled to the server by one or more interfaces 438, such as a serial port interface, parallel port, or universal serial bus (USB). The computing device 400 may further include a display 422, such as a touchscreen display.

The computing device 400 may include a variety of tangible processor-readable storage media and intangible processor-readable communication signals. Tangible processor-readable storage can be embodied by any available media that can be accessed by the computing device 400 and can include both volatile and nonvolatile storage media and removable and non-removable storage media. Tangible processor-readable storage media excludes intangible, transitory communications signals (such as signals per se) and includes volatile and nonvolatile, removable, and non-removable storage media implemented in any method, process, or technology for storage of information such as processor-readable instructions, data structures, program modules, or other data. Tangible processor-readable storage media includes but is not limited to RAM, ROM, EEPROM, flash memory or other memory technology, CDROM, digital versatile disks (DVD) or other optical disk storage, magnetic cassettes, magnetic tape, magnetic disk storage, or other magnetic storage devices, or any other tangible medium which can be used to store the desired information and which can be accessed by the computing device 400. In contrast to tangible processor-readable storage media, intangible processor-readable communication signals may embody processor-readable instructions, data structures, program modules, or other data resident in a modulated data signal, such as a carrier wave or other signal transport mechanism. The term “modulated data signal” means a signal that has one or more of its characteristics set or changed in such a manner as to encode information in the signal. By way of example, and not limitation, intangible communication signals include signals traveling through wired media such as a wired network or direct-wired connection, and wireless media such as acoustic, RF, infrared, and other wireless media.

In some aspects, the techniques described herein relate to a cooling system including: multiple heat rejection units (HRUs) arranged in a parallel configuration to provide output flows that combine to form an input flow to an information technology (IT) rack, each HRU of the multiple HRUs storing a first firmware sequence executable to: operate the HRU in a flowrate control mode for a first predefined period of time, the flowrate control mode causing a control system of the HRU to self-regulate pump speed to ensure a flowrate of coolant through the HRU is equal to a flowrate setpoint that is set to a nominal HRU flowrate target; in response to expiration of the first predefined period of time: determining a current pressure value by measuring an internal pressure within the HRU; store the current pressure value as a pressure setpoint for the HRU; and transition the HRU out of the flowrate control mode and into a pressure control mode, the pressure control mode causing the control system of the HRU to self-regulate pump speed to ensure that a measured internal pressure matches the pressure setpoint; and a processor external to the multiple HRUs that initiates flowrate equalization operations by transmitting commands that initiate the first firmware sequence in the multiple HRUs currently.

In some aspects, the techniques described herein relate to a cooling system, wherein the HRU stores a second firmware sequence for initializing the HRU as a replacement to a previous HRU removed from the cooling system, the second firmware sequence executable to: set the flowrate setpoint of the HRU equal to a reduced flowrate that is less than the nominal HRU flowrate target; operate the HRU in the flowrate control mode with the flowrate setpoint equal to reduced flowrate for a second predefined period of time; and in response to expiration of the second predefined period of time, adjusting the flowrate setpoint of the HRU to equal the nominal HRU flowrate target.

In some aspects, the techniques described herein relate to a cooling system, wherein the second firmware sequence is further executable to: subsequent to adjusting the flowrate setpoint of the HRU to equal the nominal HRU flowrate target, continuing to operate the HRU in the flowrate control mode for a third predefined period of time; and in response to expiration of the third predefined period of time, executing the first firmware sequence.

In some aspects, the techniques described herein relate to a cooling system, wherein the multiple HRUs are arranged in a parallel configuration to generate output flows that are combined to form an input flow to an information technology (IT) rack, and wherein the nominal HRU flowrate target is derived by dividing an IT rack target flow rate by a number of the HRUs arranged in the parallel configuration.

In some aspects, the techniques described herein relate to a cooling system, wherein at least two of the multiple HRUs are different distances from the IT rack and executing the first firmware sequence in the multiple HRUs ensures that each of the multiple HRUs generate output flows with identical flowrates.

In some aspects, the techniques described herein relate to a cooling system, wherein the processor external to the multiple HRUs transmits the commands that initiate the first firmware sequence during when the cooling system is initially brought online.

In some aspects, the techniques described herein relate to a cooling system including: a heat rejection unit (HRU) coupled to a coolant loop, the HRU including: a plurality of pumps and a liquid-to-air heat exchanger; and a control system that selectively regulates flow through the HRU by driving the plurality of pumps according to either of: a flowrate control mode that selectively varies speeds of the plurality of pumps to fix a flowrate of coolant through the HRU to a flowrate setpoint; or a pressure control mode that selectively varies the speeds of the plurality of pumps to fix a pressure internal to the HRU to a pressure setpoint; wherein the control system executes flowrate equalization operations that include: operating the HRU in the flowrate control mode for a first predefined period of time while receiving coolant through the coolant loop and while the flowrate setpoint is set to equal a flowrate target; after expiration of the first predefined period of time, adjusting the pressure setpoint of the HRU to equal a pressure that is measured within the HRU; and subsequent to adjusting the pressure setpoint of the HRU, disabling the flowrate control mode and enabling the pressure control mode.

In some aspects, the techniques described herein relate to a cooling system, wherein the HRU is a first HRU and the cooling system further includes a second HRU coupled to the cooling system, wherein first HRU and the second HRU generate output flows that are combined to form an input flow provided to an information technology (IT) rack.

In some aspects, the techniques described herein relate to a cooling system, wherein the first HRU and the second HRU are different distances from the IT rack and configured to execute the flowrate equalization operations at a same time.

In some aspects, the techniques described herein relate to a cooling system, wherein the flowrate target is identical in both the first HRU and the second HRU, and wherein the first predefined period of time is set to ensure that output flowrates in both the first HRU and the second HRU reach the flowrate target.

In some aspects, the techniques described herein relate to a cooling system, wherein the control system of the HRU executes the flowrate equalization operations in response to receiving a command transmitted from a device external to the HRU.

In some aspects, the techniques described herein relate to a cooling system, wherein the control system is configured to conditionally execute new HRU initialization operations that provide for: adjusting the flowrate setpoint of the HRU to equal a rate that is reduced as compared to the flowrate target; operating the HRU in the flowrate control mode for a second predefined period of time; and following expiration of the second predefined period of time, adjusting the flowrate setpoint of the HRU to equal the flowrate target.

In some aspects, the techniques described herein relate to a cooling system, wherein the new HRU initialization operations further include: subsequent to adjusting the flowrate setpoint of the HRU to equal the flowrate target, continuing to operate the HRU in the flowrate control mode for a third predefined period of time; and in response to expiration of the third predefined period of time, executing the flowrate equalization operations.

In some aspects, the techniques described herein relate to a method for operating multiple heat rejection units (HRUs) in a cooling system, the method including flowrate equalization operations that include: operating a first HRU and a second HRU in a flowrate control mode for a first predefined period of time, the flowrate control mode causing control systems of the first HRU and the second HRU to self-regulate pump speed to ensure a flowrate of coolant through the first HRU and the second HRU is equal to a flowrate setpoint stored in memory, the flowrate setpoint being equal to a nominal HRU flowrate target during the first predefined period of time; in response to expiration of the first predefined period of time: measuring an internal pressure within the first HRU and within the second HRU; adjusting a first pressure setpoint of the first HRU to equal the internal pressure measured within the first HRU; adjusting a second pressure setpoint of the second HRU to equal the internal pressure measured within the second HRU; and subsequent to adjusting the first pressure setpoint of the first HRU and the second pressure setpoint of the second HRU disabling the flowrate control mode and enabling a pressure control mode in the first HRU and in the second HRU, the pressure control mode causing the first HRU to self-regulate pump speed to maintain the internal pressure within the first HRU at the first pressure setpoint and causing the second HRU to self-regulate pump speed to maintain the internal pressure within the second HRU at the second pressure setpoint.

In some aspects, the techniques described herein relate to a method, wherein the first HRU and the second HRU generate output flows that are combined to form an input flow provided to an information technology (IT) rack.

In some aspects, the techniques described herein relate to a method, wherein the nominal HRU flowrate target is derived by dividing a target flow rate through the IT rack by a number of HRUs arranged in parallel to provide an input flow to the IT rack.

In some aspects, the techniques described herein relate to a method, wherein each of the multiple HRUs includes a control system that initiates the flowrate equalization operations in response to receiving a flowrate equalization command from an external device, and wherein the external device transmits the flowrate equalization command to each one of the multiple HRUs when the cooling system is initially brought online.

In some aspects, the techniques described herein relate to a method, wherein the method further includes executing new HRU initialization operations within a newly replaced HRU of the cooling system, the new HRU initialization operations including: adjusting the flowrate setpoint of the newly replaced HRU to a reduced flowrate target that is less than the nominal HRU flowrate target; operating the newly replaced HRU in the flowrate control mode with the flowrate setpoint set to the reduced flowrate target for a second predefined period; and in response to expiration of the second predefined period, increasing the flowrate setpoint of the newly replaced HRU to equal the nominal HRU flowrate target.

In some aspects, the techniques described herein relate to a method, further including: subsequent to increasing the flowrate setpoint to equal the nominal HRU flowrate target, operating the newly replaced HRU in the flowrate control mode for a third predefined period of time; and in response to expiration of the third predefined period, executing the flowrate equalization operations in the newly replaced HRU.

In some aspects, the techniques described herein relate to a method, wherein the new HRU initialization operations are initiated in response to receiving a command from an external device, the command being transmitted following replacement of one of the multiple HRUs with the newly replaced HRU.

The logical operations described herein are implemented as logical steps in one or more computer systems. The logical operations may be implemented (1) as a sequence of processor-implemented steps executing in one or more computer systems and (2) as interconnected machine or circuit modules within one or more computer systems. The implementation is a matter of choice, dependent on the performance requirements of the computer system being utilized. Accordingly, the logical operations making up the implementations described herein are referred to variously as operations, steps, objects, or modules. Furthermore, logical operations may be performed in any order, unless explicitly claimed otherwise or a specific order is inherently necessitated by the claim language. The above specification, examples, and data, together with the attached appendices, provide a complete description of the structure and use of exemplary implementations.

What is claimed is:

1. A cooling system comprising:
multiple heat rejection units (HRUs) arranged in a parallel configuration to provide output flows that combine to form an input flow to an information technology (IT) rack, each HRU of the multiple HRUs storing a first firmware sequence executable to:
operate the HRU in a flowrate control mode for a first predefined period of time, the flowrate control mode causing a control system of the HRU to self-regulate pump speed to ensure a flowrate of coolant through the HRU is equal to a flowrate setpoint that is set to a nominal HRU flowrate target;
in response to expiration of the first predefined period of time:
determining a current pressure value by measuring an internal pressure within the HRU;
store the current pressure value as a pressure setpoint for the HRU; and
transition the HRU out of the flowrate control mode and into a pressure control mode, the pressure control mode causing the control system of the HRU to self-regulate pump speed to ensure that a measured internal pressure matches the pressure setpoint; and
a processor external to the multiple HRUs that initiates flowrate equalization operations by transmitting commands that initiate the first firmware sequence in the multiple HRUs currently.

2. The cooling system of claim 1, wherein the HRU stores a second firmware sequence for initializing the HRU as a replacement to a previous HRU removed from the cooling system, the second firmware sequence executable to:
set the flowrate setpoint of the HRU equal to a reduced flowrate that is less than the nominal HRU flowrate target;
operate the HRU in the flowrate control mode with the flowrate setpoint equal to reduced flowrate for a second predefined period of time; and
in response to expiration of the second predefined period of time, adjusting the flowrate setpoint of the HRU to equal the nominal HRU flowrate target.

3. The cooling system of claim 2, wherein the second firmware sequence is further executable to:
subsequent to adjusting the flowrate setpoint of the HRU to equal the nominal HRU flowrate target, continuing to operate the HRU in the flowrate control mode for a third predefined period of time; and
in response to expiration of the third predefined period of time, executing the first firmware sequence.

4. The cooling system of claim 1, wherein the multiple HRUs are arranged in a parallel configuration to generate output flows that are combined to form an input flow to an information technology (IT) rack, and wherein the nominal HRU flowrate target is derived by dividing an IT rack target flow rate by a number of the HRUs arranged in the parallel configuration.

5. The cooling system of claim 1, wherein at least two of the multiple HRUs are different distances from the IT rack and executing the first firmware sequence in the multiple HRUs ensures that each of the multiple HRUs generate output flows with identical flowrates.

6. The cooling system of claim 1, wherein the processor external to the multiple HRUs transmits the commands that initiate the first firmware sequence during when the cooling system is initially brought online.

7. A cooling system comprising:
a heat rejection unit (HRU) coupled to a coolant loop, the HRU comprising:
a plurality of pumps and a liquid-to-air heat exchanger; and
a control system that selectively regulates flow through the HRU by driving the plurality of pumps according to either of:
a flowrate control mode that selectively varies speeds of the plurality of pumps to fix a flowrate of coolant through the HRU to a flowrate setpoint; or
a pressure control mode that selectively varies the speeds of the plurality of pumps to fix a pressure internal to the HRU to a pressure setpoint;
wherein the control system executes flowrate equalization operations that comprise:
operating the HRU in the flowrate control mode for a first predefined period of time while receiving coolant through the coolant loop and while the flowrate setpoint is set to equal a flowrate target;
after expiration of the first predefined period of time, adjusting the pressure setpoint of the HRU to equal a pressure that is measured within the HRU; and
subsequent to adjusting the pressure setpoint of the HRU, disabling the flowrate control mode and enabling the pressure control mode.

8. The cooling system of claim 7, wherein the HRU is a first HRU and the cooling system further comprises a second HRU coupled to the cooling system, wherein first HRU and the second HRU generate output flows that are combined to form an input flow provided to an information technology (IT) rack.

9. The cooling system of claim 8, wherein the first HRU and the second HRU are different distances from the IT rack and configured to execute the flowrate equalization operations at a same time.

10. The cooling system of claim 9, wherein the flowrate target is identical in both the first HRU and the second HRU, and wherein the first predefined period of time is set to ensure that output flowrates in both the first HRU and the second HRU reach the flowrate target.

11. The cooling system of claim 8, wherein the control system of the HRU executes the flowrate equalization operations in response to receiving a command transmitted from a device external to the HRU.

12. The cooling system of claim 8, wherein the control system is configured to conditionally execute new HRU initialization operations that provide for:
adjusting the flowrate setpoint of the HRU to equal a rate that is reduced as compared to the flowrate target;
operating the HRU in the flowrate control mode for a second predefined period of time; and
following expiration of the second predefined period of time, adjusting the flowrate setpoint of the HRU to equal the flowrate target.

13. The cooling system of claim 12, wherein the new HRU initialization operations further comprise:
subsequent to adjusting the flowrate setpoint of the HRU to equal the flowrate target, continuing to operate the HRU in the flowrate control mode for a third predefined period of time; and
in response to expiration of the third predefined period of time, executing the flowrate equalization operations.

14. A method for operating multiple heat rejection units (HRUs) in a cooling system, the method comprising flowrate equalization operations that comprise:
operating a first HRU and a second HRU in a flowrate control mode for a first predefined period of time, the flowrate control mode causing control systems of the first HRU and the second HRU to self-regulate pump speed to ensure a flowrate of coolant through the first HRU and the second HRU is equal to a flowrate setpoint stored in memory, the flowrate setpoint being equal to a nominal HRU flowrate target during the first predefined period of time;
in response to expiration of the first predefined period of time:
measuring an internal pressure within the first HRU and within the second HRU;
adjusting a first pressure setpoint of the first HRU to equal the internal pressure measured within the first HRU;
adjusting a second pressure setpoint of the second HRU to equal the internal pressure measured within the second HRU; and
subsequent to adjusting the first pressure setpoint of the first HRU and the second pressure setpoint of the second HRU disabling the flowrate control mode and enabling a pressure control mode in the first HRU and in the second HRU, the pressure control mode causing the first HRU to self-regulate pump speed to maintain the internal pressure within the first HRU at the first pressure setpoint and causing the second HRU to self-regulate pump speed to maintain the internal pressure within the second HRU at the second pressure setpoint.

15. The method of claim 14, wherein the first HRU and the second HRU generate output flows that are combined to form an input flow provided to an information technology (IT) rack.

16. The method of claim 15, wherein the nominal HRU flowrate target is derived by dividing a target flow rate through the IT rack by a number of HRUs arranged in parallel to provide an input flow to the IT rack.

17. The method of claim 14, wherein each of the multiple HRUs includes a control system that initiates the flowrate equalization operations in response to receiving a flowrate equalization command from an external device, and wherein the external device transmits the flowrate equalization command to each one of the multiple HRUs when the cooling system is initially brought online.

18. The method of claim 17, wherein the method further comprises executing new HRU initialization operations within a newly replaced HRU of the cooling system, the new HRU initialization operations comprising:
adjusting the flowrate setpoint of the newly replaced HRU to a reduced flowrate target that is less than the nominal HRU flowrate target;
operating the newly replaced HRU in the flowrate control mode with the flowrate setpoint set to the reduced flowrate target for a second predefined period; and
in response to expiration of the second predefined period, increasing the flowrate setpoint of the newly replaced HRU to equal the nominal HRU flowrate target.

19. The method of claim 18, further comprising:
subsequent to increasing the flowrate setpoint to equal the nominal HRU flowrate target, operating the newly replaced HRU in the flowrate control mode for a third predefined period of time; and
in response to expiration of the third predefined period, executing the flowrate equalization operations in the newly replaced HRU.

20. The method of claim 19, wherein the new HRU initialization operations are initiated in response to receiving a command from an external device, the command being transmitted following replacement of one of the multiple HRUs with the newly replaced HRU.
